(19) United States
(12) Patent Application Publication
(10) Pub. No.: US 2019/0319222 A1
(43) Pub. Date: Oct. 17, 2019

(54) PHOTOMASK AND METHOD FOR MANUFACTURING DISPLAY DEVICE

(71) Applicant: Sharp Kabushiki Kaisha, Sakai City, Osaka (JP)

(72) Inventors: Ryosuke GUNJI, Sakai City (JP); Tohru OKABE, Sakai City (JP); Hiroki TANIYAMA, Sakai City (JP); Shinji ICHIKAWA, Sakai City (JP); Shinsuke SAIDA, Sakai City (JP); Hiroharu JINMURA, Sakai City (JP); Yoshihiro NAKADA, Sakai City (JP); Akira INOUE, Sakai City (JP)

(21) Appl. No.: 16/471,591

(22) PCT Filed: Sep. 29, 2017
(86) PCT No.: PCT/JP2017/035705

§ 371 Date: Jun. 20, 2019

(51) Int. Cl. H01L 51/56; H01L 27/32; G03F 1/32; G03F 1/38

(52) U.S. Cl. CPC H01L 51/56; H01L 27/3246; G03F 1/38; G03F 1/32; H01L 27/3283

(57) ABSTRACT

The photomask includes: transmissive portions configured to form the opening portion, a semi-transmitted light portion configured to form the planar portion, and a light blocking portion configured to form each of the plurality of photo spacer portions. The light blocking portion is formed in an island shape between the transmissive portions arranged in a lattice shape, and an end portion of the light blocking portion is formed to extend, between two of the transmissive portions, along outer edges of the two of the transmissive portions.

### TECHNICAL FIELD

The disclosure relates to a photomask, a display device using the photomask, and a method for manufacturing the display device.

### BACKGROUND ART

There are known display devices that include an edge cover (insulating film) for covering the peripheral edge of the anode electrode (lower electrode) of the organic light emitting diode, and a photo spacer (rib) formed on the anode electrode and functioning as a spacer of a fine metal mask for vapor-depositing the luminescent material (PTL 1 ).

The edge cover is formed in a state where it is covering the peripheral edge of the anode electrode, and the anode electrode is exposed from the window formed in the edge cover. Thereafter, a photo spacer is formed on the edge cover.

### CITATION LIST

### Patent Literature

PTL 1: JP 2001-195008 A (published on Jul. 19, 2001).

### SUMMARY

### Technical Problem

Forming the edge cover and photo spacer collectively by using a photomask having a gray tone pattern is advantageous because two exposure steps are replaced by one exposure step.

However, in a case of forming a plurality of small photo spacers, there is a phenomenon in which the photo spacer is deformed due to heat sagging generated in baking, and the height of the photo spacer becomes lower. The phenomenon is particularly problematic in high resolution display devices.

### Solution to Problem

A photomask according to one aspect of the disclosure is a photomask configured to collectively form an edge cover, out of photomasks configured to form a display device, the display device including:

a plurality of first electrodes;

the edge cover configured to cover end portions of the plurality of first electrodes;

a light-emitting layer in an island shape, the light-emitting layer being configured to cover each of the plurality of first electrodes and a part of the edge cover; and

a second electrode,

wherein the edge cover includes

an opening portion configured to expose the plurality of first electrodes,

a planar portion, and

a plurality of photo spacer portions higher than the planar portion,

the photomask includes

transmissive portions configured to form the opening portion,

a semi-transmitted light portion configured to form the planar portion, and

a light blocking portion configured to form each of the plurality of photo spacer portions,

the light blocking portion is formed in an island shape between the transmissive portions arranged in a lattice shape, and

an end portion of the light blocking portion is formed to extend, between two of the transmissive portions, along outer edges of the two of the transmissive portions.

### Advantageous Effects of Disclosure

According to one aspect of the disclosure, it is possible to prevent decrease of the height of the photo spacer due to heat sagging in baking.

### BRIEF DESCRIPTION OF DRAWINGS

FIG. 1 is a plan view schematically illustrating a configuration of a photomask according to a first embodiment.

FIG. 2 is a cross-sectional view taken along the plane A-A illustrated in FIG. 1.

FIG. 3 is a plan view schematically illustrating a configuration of a photomask according to a comparative example.

FIG. 4A is a cross-sectional view of the substrate and the photosensitive organic layer before baking according to the comparative example, FIG. 4B is a cross-sectional view of the substrate and the photosensitive organic layer after baking according to the comparative example, FIG. 4C is a cross-sectional view of the substrate and the photosensitive organic layer before baking according to the first embodiment, and FIG. 4D is a cross-sectional view of the substrate and the photosensitive organic layer after baking according to the first embodiment.

FIG. 5A is a plan view illustrating a modified example of the photomask according to the first embodiment, and FIG. 5B is a plan view illustrating another modified example.

FIGS. 6A and 6B are plan views illustrating still other modified examples of the photomask.

FIGS. 7A and 7B are plan views illustrating still other modified examples of the photomask.

FIG. 8 is a plan view illustrating still another modified example of the photomask.

### DESCRIPTION OF EMBODIMENTS

In the following, embodiments of the disclosure will be described.

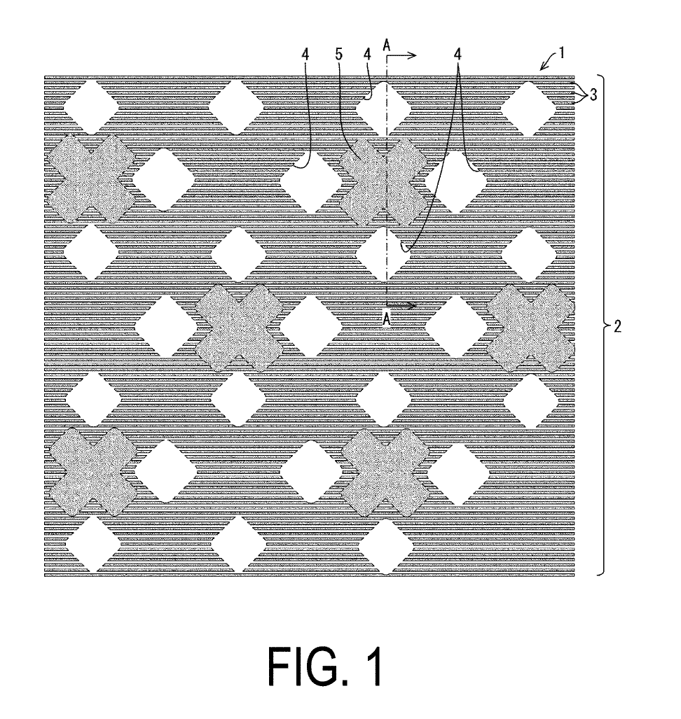

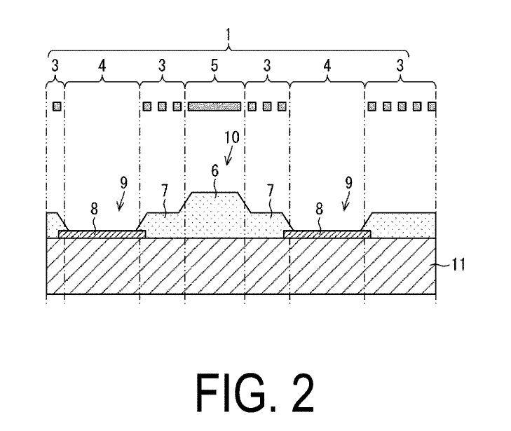

FIG. 1 is a plan view schematically illustrating a configuration of the photomask 1 according to the first embodiment. FIG. 2 is a cross-sectional view taken along the plane A-A illustrated in FIG. 1.

The photomask 1 is used to collectively form a photosensitive organic layer 10 (edge cover) including a plurality of openings 9 (opening portion) for vapor-depositing the luminescent material of the organic light emitting diode, a plurality of photo spacers 6 (photo spacer portion) for supporting a fine metal mask (not illustrated) for vapor-depositing the luminescent material, and a planar portion 7 for connecting the photo spacer 6 and the opening 9.

The photosensitive organic layer 10 is formed of polyimide resin, acrylic resin, epoxy resin, and the like. Then, a photo spacer 6, a planar portion 7 and an opening 9 are formed in the photosensitive organic layer 10. The opening 9 exposes the anode electrode 8 (first electrode), and an end portion of the anode electrode 8 is covered with the planar portion 7.

Then, a light-emitting layer in an island shape (not illustrated) covering the anode electrode 8 and a part of the photosensitive organic layer 10 is formed by using vapor deposition method by which the luminescent material is vapor-deposited on the anode electrode 8 and the photosensitive organic layer 10. A cathode electrode (second electrode) is formed on the light-emitting layer.

The photomask 1 includes a gray-tone region 2 (semi-transmitted light portion, gray-tone mask) in which a plurality of belt-shaped patterns 3 (fine patterns) are formed in parallel with each other, a plurality of opening patterns 4 (transmissive portions) formed in the gray-tone region 2 across the plurality of belt-shaped patterns 3 to form a plurality of openings 9, and a plurality of light blocking patterns 5 (light blocking portions) formed in the gray-tone region 2 across the plurality of belt-shaped patterns 3 to form a plurality of photo spacers 6. In the example illustrated in FIG. 1, each of the plurality of opening patterns 4 is formed in a quadrilateral shape, and the plurality of opening patterns 4 are arranged in a matrix shape. Then, each light blocking pattern 5 is arranged at a position surrounded by four opening patterns 4 arranged in two rows and two columns.

Each light blocking pattern 5 is formed in a cross shape to extend along outer edges of each of the four opening patterns arranged in two rows and two columns. The light blocking patterns 5 is formed in an island shape between the plurality of opening patterns 4 arranged in a lattice pattern. An end portion of the light blocking pattern 5 sandwiched between two opening patterns 4 is formed to extend along the outer edges of the two opening patterns 4. The light blocking pattern 5 is formed so that its peripheral edge is in contact with the belt-shaped pattern 3.

An opening 9 is formed by the opening pattern 4 of the photomask 1, a photo spacer 6 is formed by the light blocking pattern 5, and a planar portion 7 is formed by the belt-shaped pattern 3.

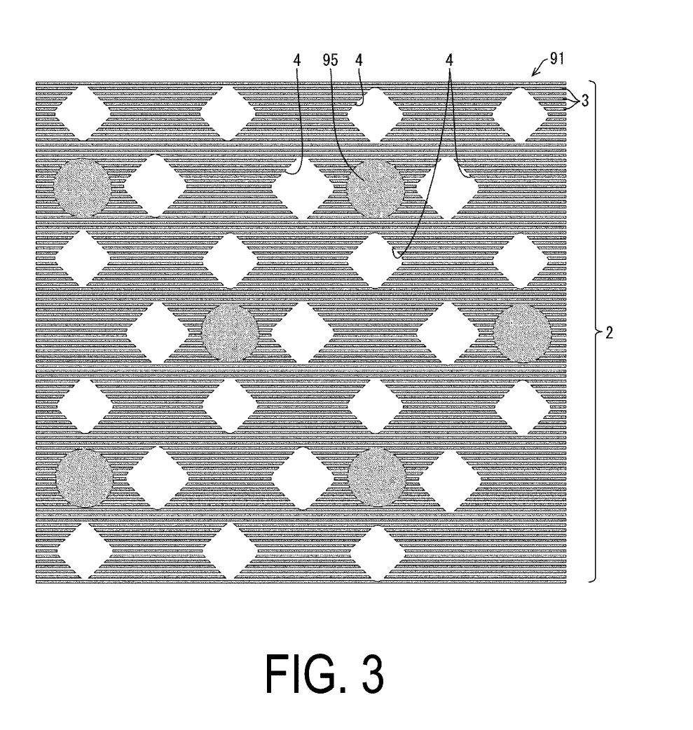

FIG. 3 is a plan view schematically illustrating a configuration of the photomask 91 according to a comparative example. The photomask 91 includes a gray-tone region 2 in which a plurality of belt-shaped patterns 3 are formed in parallel with each other, a plurality of opening patterns 4 in a quadrilateral shape, the plurality of opening patterns 4 being formed in a matrix shape in the gray-tone region 2 across the plurality of belt-shaped patterns 3 to form a plurality of openings 9, and a plurality of light blocking patterns 95 formed in the gray-tone region 2 across the plurality of belt-shaped patterns 3 to form a plurality of photo spacers 6. Each light blocking pattern 95 is formed in a circular shape at a position surrounded by four opening patterns 4 arranged in two rows and two columns.

Thus, in a case of forming a small light blocking pattern 95 in a circular shape, there is a phenomenon in which the photo spacer is deformed due to heat sagging generated in the photo spacer in baking the photo spacer formed by the light blocking pattern 95, and the height of the photo spacer becomes lower. This phenomenon is particularly problematic in high resolution OLED panels.

On the other hand, in the present embodiment, as illustrated in FIG. 1, the light blocking pattern 5 is formed in a cross shape such that the end portions of the light blocking pattern 5, each being arranged in the gap between adjacent opening patterns 4, extend along the outer edges of each of the four opening patterns 4 arranged in two rows and two columns. Therefore, the area of the light blocking pattern 5 increases. Therefore, the volume of the photo spacer 6 formed by the light blocking pattern 5 increases. As a result, regardless of the pattern density, a volume that can increase the height of the photo spacer 6 is secured, and decrease of the height of the photo spacer 6 due to heat sagging is prevented.

It should be noted that an example in which the light blocking pattern 95 corresponding to the photo spacer is circular is illustrated, but the disclosure is not limited thereto. The light blocking pattern 95 may have other shapes, such as a rectangle, rhombus, and ellipse, that do not extend along the opening pattern 4.

In addition, an example is illustrated in which the light blocking pattern is arranged at a position surrounded by four opening patterns arranged in two rows and two columns, but the disclosure is not limited thereto. For example, the light blocking pattern may be arranged at a position surrounded by two or three opening patterns.

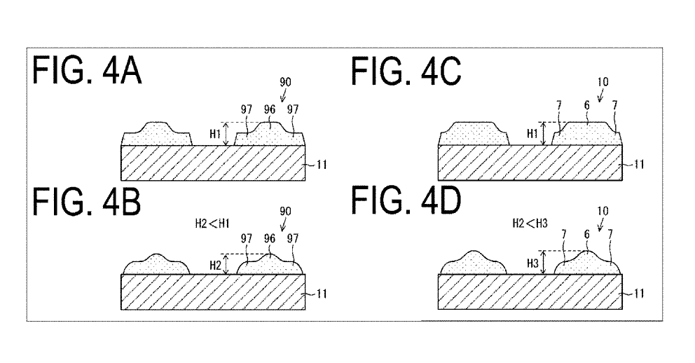

FIG. 4A is a cross-sectional view of the substrate 11 and the photosensitive organic layer 90 before baking according to the comparative example, FIG. 4B is a cross-sectional view of the substrate 11 and the photosensitive organic layer 90 after baking according to the comparative example, FIG. 4C is a cross-sectional view of the substrate 11 and the photosensitive organic layer 10 before baking according to the first embodiment, and FIG. 4D is a cross-sectional view of the substrate 11 and the photosensitive organic layer 10 after baking according to the first embodiment.

By using the photomask 91 illustrated in FIG. 3, a photo spacer 96 and an edge cover 97 are formed in the photosensitive organic layer 90 on the substrate 11 as illustrated in FIG. 4A. A phenomenon occurs in which the photo spacer 96 is deformed due to heat sagging generated in the photo spacer 96 in baking, and the height H1 of the photo spacer 96 changes to a height H2 lower than the height H1 as illustrated in FIG. 4B.

On the other hand, in the present embodiment, since the volume of the photo spacer 6 formed by the light blocking pattern 5 increases compared to the volume of the photo spacer 96 in FIG. 4A, the height of the photo spacer 6 changes, after baking, to a height H3 higher than the height H2 of the comparative example as illustrated in FIG. 4D. Thus, the decrease of the height of the photo spacer 6 due to heat sagging is suppressed.

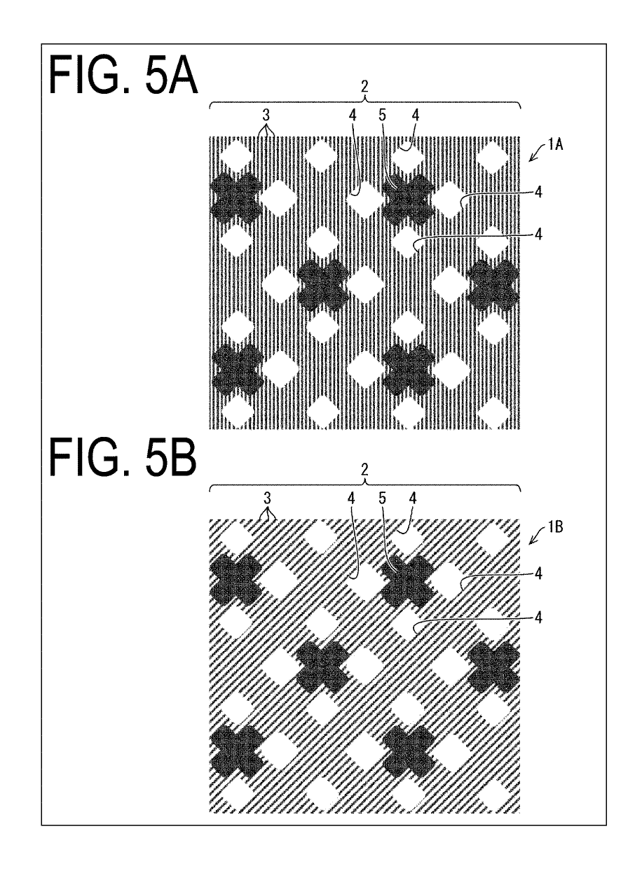

FIG. 5A is a plan view illustrating a modified example of the photomask according to the first embodiment, and FIG. 5B is a plan view illustrating another modified example. Constituent elements similar to the constituent elements described above are given the same reference numerals. The detailed description of these constituent elements will not be repeated.

Photomasks 1A and 1B each include a gray-tone region 2 in which a plurality of belt-shaped patterns 3 are formed in parallel with each other. In the above example, an example is described in which the belt-shaped pattern 3 extends in the horizontal direction, but the disclosure is not limited thereto. The belt-shaped pattern 3 may extend in any direction, and for example, may extend in a vertical direction as illustrated in FIG. 5A or in an oblique direction as illustrated in FIG. 5B.

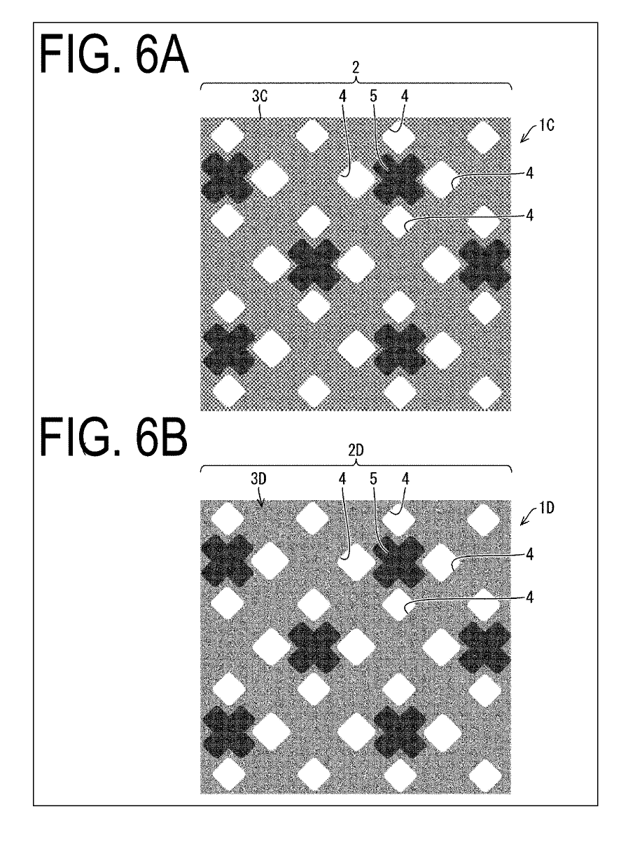

FIGS. 6A and 6B are plan views illustrating yet other modified examples of the photomask. Constituent elements similar to the constituent elements described above are given the same reference numerals. The detailed description of these constituent elements will not be repeated.

As illustrated in FIG. 6A, the photomask 1C includes a gray-tone region 2 including a pattern 3C such as a polka dot pattern. In the above example, an example is described in which the belt-shaped pattern 3 is formed in the gray-tone region 2, but the disclosure is not limited thereto. Instead of the belt-shaped pattern 3, another pattern 3C such as a polka dot pattern or a checkered pattern may be formed.

As illustrated in FIG. 6B, the photomask 1D includes a halftone region 2D including a halftone pattern 3D. In the above example, an example of the gray-tone region 2 is described, but the disclosure is not limited thereto. A halftone region 2D may be included instead of the gray-tone region 2.

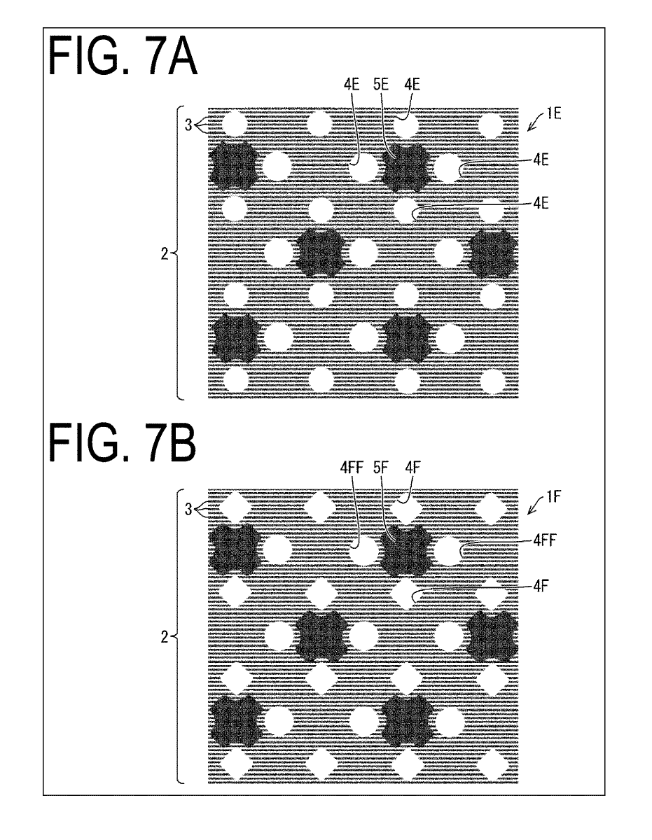

FIGS. 7A and 7B are plan views illustrating still other modified examples of the photomask. Constituent elements similar to the constituent elements described above are given the same reference numerals. The detailed description of these constituent elements will not be repeated.

In the above example, an example of the rectangular opening pattern 4 is described, but the disclosure is not limited thereto. Instead of the rectangular opening pattern 4, a circular opening pattern 4E may be formed as illustrated in FIG. 7A. In this case, a light blocking pattern SE is formed that is shaped along the peripheral edges of four circular opening patterns 4E in two rows and two columns. The opening pattern may be another shape such as a rectangle, a rhombus, or an ellipse.

In addition, the shape of each opening pattern may be different depending on the color (red (R), green (G), blue (B)) of the luminescent material of the organic light emitting diode formed in a corresponding opening 9, and for example, as illustrated in FIG. 7B, opening patterns 4F and 4FF having different shapes may be formed.

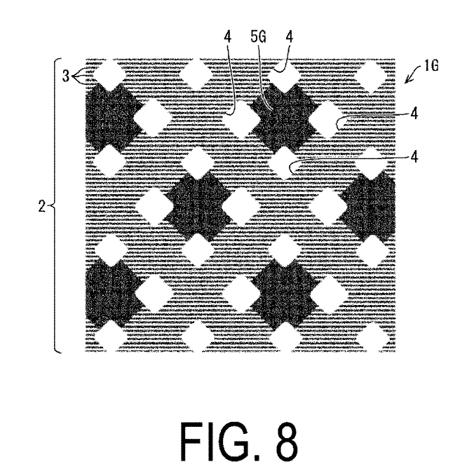

FIG. 8 is a plan view illustrating still another modified example of the photomask. Constituent elements similar to the constituent elements described above are given the same reference numerals. The detailed description of these constituent elements will not be repeated.

In the above example, a configuration in which the planar portion 7 is provided between the opening 9 and the photo spacer 6 is described, but the disclosure is not limited thereto. The planar portion 7 may not be provided. In this case, the light blocking pattern SG is formed such that the end portions of the light blocking pattern SG each are in close contact with a part of the peripheral edge of each opening pattern 4 as illustrated in FIG. 8.

A positive-working photosensitive organic layer 10 is used in the above description. In a case that the positive-working photosensitive organic layer 10 is exposed to light, the solubility in a developing solution increases and the exposed portion is removed. A negative-working photosensitive organic layer may also be used in the description. In a case that the negative-working photosensitive organic layer is exposed to light, the solubility in a developing solution decreases and the exposed portion remains after development. In the case of the negative-working, the transmissive portion forms a photo spacer portion, the semi-transmitted light portion forms a planar portion, and the light blocking portion forms an opening. In addition, in the above description, an example of forming the edge cover with the photosensitive organic layer is described, but the organic layer may be patterned by using a resist separately without using a photosensitive organic layer.

### SUPPLEMENT

A photomask of the first aspect is a photomask configured to collectively form an edge cover, out of photomasks configured to form a display device, the display device including:

a plurality of first electrodes;

the edge cover configured to cover end portions of the plurality of first electrodes;

a light-emitting layer in an island shape, the light-emitting layer being configured to cover each of the plurality of first electrodes and a part of the edge cover; and

a second electrode,

wherein the edge cover includes

an opening portion configured to expose the plurality of first electrodes,

a planar portion, and

a plurality of photo spacer portions higher than the planar portion,

the photomask includes

transmissive portions configured to form the opening portion,

a semi-transmitted light portion configured to form the planar portion, and

a light blocking portion configured to form each of the plurality of photo spacer portions,

the light blocking portion is formed in an island shape between the transmissive portions arranged in a lattice shape, and

an end portion of the light blocking portion is formed to extend, between two of the transmissive portions, along outer edges of the two of the transmissive portions.

In the second aspect, each of the transmissive portions is formed in a quadrilateral shape.

In the third aspect, the semi-transmitted light portion includes a pattern in which a plurality of belt-shaped patterns are formed in parallel with each other.

In the fourth aspect, a peripheral edge of the light blocking portion is in contact with the semi-transmitted light portion.

In the fifth aspect, a peripheral edge of the light blocking portion is partly in contact with the transmissive portions.

In the sixth aspect, the semi-transmitted light portion is formed by a halftone mask.

In the seventh aspect, the semi-transmitted light portion is formed by a gray-tone mask provided with a fine pattern.

The display device of the eighth aspect is a display device including an edge cover configured to cover end portions of a plurality of first electrodes,

wherein the edge cover includes

at least one opening portion configured to expose each of the plurality of first electrodes,

a planar portion, and

a plurality of photo spacer portions higher than the planar portion,

the display device further includes

a light-emitting layer in an island shape, the light-emitting layer being configured to cover each of the plurality of first electrodes and a part of the edge cover, and

a second electrode in an upper layer than the light-emitting layer, the second electrode being a common electrode to each of the plurality of first electrodes,

the at least one opening portion includes a plurality of opening portions,

each of the plurality of photo spacer portions is formed in an island shape between the plurality of opening portions arranged in a lattice shape, and

an end portion of each of the plurality of photo spacer portions is formed to extend, between two of the plurality of opening portions, along outer edges of the two of the plurality of opening portions.

The method for manufacturing a display device of the ninth aspect is a method for manufacturing a display device by using the photomask according to the first aspect, the method including:

forming the edge cover on a substrate;

mounting the photomask on the edge cover; and

irradiating the edge cover with light through the photomask to form each of the plurality of photo spacer portions along an outer edge of the opening portion.

The disclosure is not limited to each of the above embodiments, and various modifications are possible within the scope indicated in the claims, and embodiments obtained by appropriately combining technical means disclosed in each of different embodiments are also included in the technical scope of the disclosure. Furthermore, combining technical means disclosed in each embodiment allows new technical characteristics to be formed.

The display according to the present embodiment is not particularly limited as long as it is a display panel including a display element. The display element is a display element whose luminance and transmittance are controlled by the current, and the display element under the current control includes an organic electro luminescence (EL) display including an organic light emitting diode (OLED), or a quantum dot light emitting diode (QLED) display including an EL display QLED such as an inorganic EL display including an inorganic light emitting diode.

### REFERENCE SIGNS LIST

1 Photomask
2 Gray-tone region (semi-transmitted light portion, gray-tone mask)
3 Belt-shaped pattern (fine pattern)
4 Opening pattern (transmissive portion)
5 Light blocking pattern (light blocking portion)
6 Photo spacer (photo spacer portion)
7 Planar portion
8 Anode electrode (first electrode)
9 Opening (opening portion)
10 Photosensitive organic layer (edge cover)

1. A photomask configured to collectively form an edge cover, out of photomasks configured to form a display device, the display device comprising:
a plurality of first electrodes;
the edge cover configured to cover end portions of the plurality of first electrodes;
a light-emitting layer in an island shape, the light-emitting layer being configured to cover each of the plurality of first electrodes and a part of the edge cover; and
a second electrode,
wherein the edge cover includes
an opening portion configured to expose the plurality of first electrodes,
a planar portion, and
a plurality of photo spacer portions higher than the planar portion,
the photomask includes
transmissive portions configured to form the opening portion,
a semi-transmitted light portion configured to form the planar portion, and
a light blocking portion configured to form each of the plurality of photo spacer portions,
the light blocking portion is formed in an island shape between the transmissive portions arranged in a lattice shape, and
an end portion of the light blocking portion is formed to extend, between two of the transmissive portions, along outer edges of the two of the transmissive portions.

2. The photomask according to claim 1,
wherein each of the transmissive portions is formed in a quadrilateral shape.

3. The photomask according to claim 1,
wherein the semi-transmitted light portion includes a pattern in which a plurality of belt-shaped patterns are formed in parallel with each other.

4. The photomask according to claim 1,
wherein a peripheral edge of the light blocking portion is in contact with the semi-transmitted light portion.

5. The photomask according to claim 1,
wherein a peripheral edge of the light blocking portion is partly in contact with the transmissive portions.

6. The photomask according to claim 1,
wherein the semi-transmitted light portion is formed by a halftone mask.

7. The photomask according to claim 1,
wherein the semi-transmitted light portion is formed by a gray-tone mask provided with a fine pattern.

8. (canceled)

9. A method for manufacturing a display device by using a photomask,
the display device comprising an edge cover configured to cover end portions of a plurality of first electrodes,
wherein the edge cover includes
at least one opening portion configured to expose each of the first electrodes,
a planar portion, and
a plurality of photo spacer portions higher than the planar portion,
the display device further includes
a light-emitting layer in an island shape, the light-emitting layer being configured to cover each of the plurality of first electrodes and a part of the edge cover, and
a second electrode in an upper layer than the light-emitting layer, the second electrode being a common electrode to each of the plurality of first electrodes,
the at least one opening portion comprises a plurality of opening portions,
each of the plurality of photo spacer portions is formed in an island shape between the plurality of opening portions arranged in a lattice shape, and
an end portion of each of the plurality of photo spacer portions is formed to extend, between two of the plurality of opening portions, along outer edges of the two of the plurality of opening portions, the method comprising:
forming the edge cover on a substrate;
mounting the photomask on the edge cover; and
irradiating the edge cover with light through the photomask to form each of the plurality of photo spacer portions along an outer edge of the opening portion.
